(19) United States
(12) Patent Application Publication
(10) Pub. No.: US 2013/0037903 A1
(43) Pub. Date: Feb. 14, 2013

(54) DISPLAY DEVICE

(71) Applicants: Hiroyuki Kaigawa, Osaka (JP); Isao Nakanishi, Osaka (JP)

(72) Inventors: Hiroyuki Kaigawa, Osaka (JP); Isao Nakanishi, Osaka (JP)

(73) Assignee: SHARP KABUSHIKI KAISHA, Osaka (JP)

(21) Appl. No.: 13/641,443

(22) PCT Filed: Apr. 5, 2011
(86) PCT No.: PCT/JP2011/058596

§ 371 Date: Oct. 22, 2012

(30) Foreign Application Priority Data
Apr. 16, 2010 (JP) 2010-095494

(51) Int. Cl. H01L 31/0232

(52) U.S. Cl. 257/435; 257/E31.127

(57) ABSTRACT

Disclosed is a display device that is configured such that light that is emitted from a backlight or the like and that illuminates a display panel is prevented from being transmitted through a light-shielding layer that is provided between a light sensor element and a substrate. A liquid crystal display device 1 is provided with: a photodiode 10, which is formed on a substrate 30 that constitutes a part of the display panel; and a light-shielding film 20, which is formed between the substrate 30 and the photodiode 10. The thickness of the light-shielding film 20 is 100 nm or more.

### TECHNICAL FIELD

The present invention relates to a display device that has a light sensor element.

### BACKGROUND ART

A display device that has a light-shielding layer between a substrate that constitutes a portion of the display panel and a light sensor element formed on the substrate has been known since before. In such a display device, light incident from the substrate side is shielded using a light reflective film (light-shielding layer) disposed between the light sensor element and the substrate, as disclosed in Japanese Patent Application Laid-Open Publication No. 2009-75385, for example. As a result, external light that is transmitted through the light sensor element is reflected off of the light reflective film and enters the light sensor element again, while light from the backlight incident from the substrate side is shielded by the light reflective film.

### SUMMARY OF THE INVENTION

However, as described above, even if a light-shielding layer is formed between the light sensor element and the substrate, if the light-shielding layer is thin, then there is a possibility that light radiated from a backlight or the like will be transmitted through the light-shielding layer. If this happens, then noise occurs in the light sensor element, reducing detection accuracy.

An object of the present invention is to obtain a configuration that prevents light from the backlight or the like that illuminates the display panel from being transmitted through the light-shielding layer provided between the light sensor element and the substrate.

A display device according to one aspect of the present invention includes: a light sensor element formed on a substrate that constitutes one portion of a display panel; and a light-shielding layer interposed between the substrate and the light sensor element, wherein the thickness of a minimum thickness part of the light-shielding layer is at least 100 nm.

With the present invention, light from a backlight or the like can be prevented from being transmitted through the light-shielding layer provided between the light sensor element and the substrate.

### BRIEF DESCRIPTION OF THE DRAWINGS

FIG. 1 is a perspective view that shows a schematic configuration of a display panel of a liquid crystal display device according to an embodiment.

FIG. 2 is a cross-sectional view showing a schematic configuration of a photodiode of a liquid crystal display device according to an embodiment.

FIG. 3 is a drawing that shows light incident upon a photodiode being reflected off of the light-shielding layer.

FIG. 4 is a graph that shows the relation between the thickness of the light-shielding film and the light transmittance.

FIG. 5 is a graph that shows a magnified view of a portion of the range of FIG. 4.

FIG. 6A is a drawing that shows a state in which a resist pattern is formed on a light-shielding thin film in a manufacturing step of the light-shielding film.

FIG. 6B is a drawing that shows a state in which a light-shielding film is formed by etching the light-shielding thin film with the resist pattern as a mask in a manufacturing step of the light-shielding film.

FIG. 6C is a drawing that shows a state in which a resist pattern for forming recesses is formed on the light-shielding film in a manufacturing step of the light-shielding film.

FIG. 6D is a drawing that shows a state in which the recesses are formed on the light-shielding film by etching the light-shielding film with the resist pattern as a mask in a manufacturing step of the light-shielding film.

FIG. 6E is a drawing that shows a state in which the resist pattern on the light-shielding film is removed in a manufacturing step of the light-shielding film.

FIG. 7A is a drawing that shows a state in which a resist pattern is formed on a light-shielding thin film in a different manufacturing step of a light-shielding film.

FIG. 7B is a drawing that shows a state in which a light shielding film is formed by etching the light-shielding thin film with the resist pattern as a mask in a different manufacturing step of the light-shielding film.

FIG. 7C is a drawing that shows a state in which an island-shaped resist pattern is formed by removing thin parts of the resist pattern through ashing in a different manufacturing step of the light-shielding film.

FIG. 7D is a drawing that shows a state in which recesses are formed on the light-shielding film by etching the light-shielding film with the resist pattern as the mask in a different manufacturing step of the light-shielding film.

### DETAILED DESCRIPTION OF EMBODIMENTS

A display device according to one embodiment of the present invention includes: a light sensor element formed on a substrate that constitutes a part of a display panel; and a light-shielding layer formed between the substrate and the light sensor element, wherein the thickness of a minimum thickness part of the light-shielding layer is at least 100 nm (first configuration).

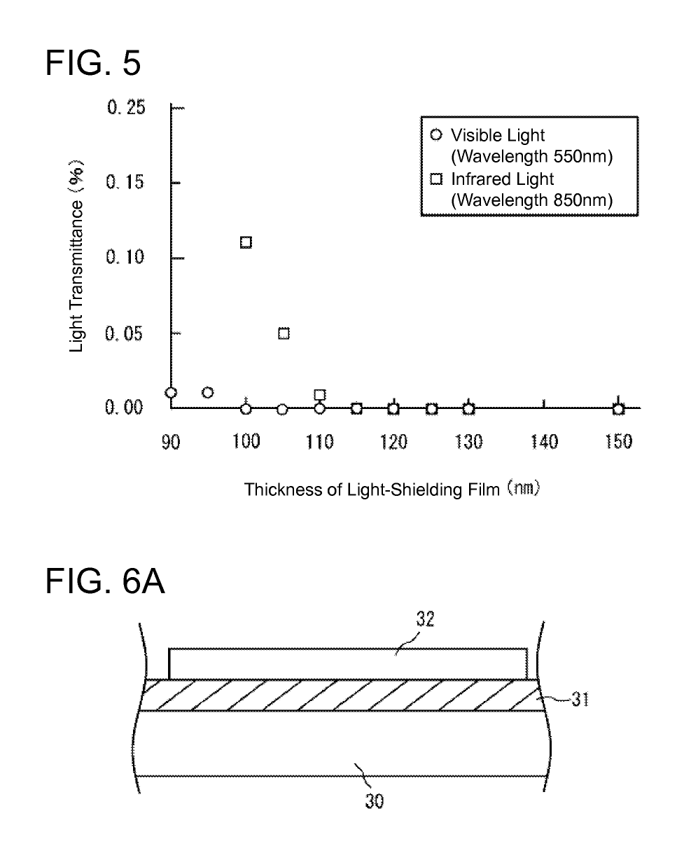

With this configuration, the light-shielding layer interposed between the substrate and the light sensor element can prevent light from a backlight or the like incident from the substrate side from being transmitted through the light-shielding layer due to having a sufficient thickness to shield the light. In other words, as shown in FIGS. 4 and 5, if the light-shielding layer has a thickness of at least 100 nm, almost no visible light is transmitted, and therefore, light from a backlight can be prevented from reaching the light sensor element. Therefore, according to the above configuration, a decrease in detection accuracy of the light sensor element can be prevented.

In the aforementioned first configuration, it is preferable that the thickness of the minimum thickness part of the light-shielding layer be at least 115 nm (second configuration).

With this configuration, as shown in FIGS. 4 and 5, it is possible to shield not only visible light, but also infrared light, using the light-shielding layer. Therefore, with the above configuration, it is possible to prevent visible light and infrared light from entering the light sensor element, and thus, a decrease in detection accuracy of the light sensor element can be effectively prevented.

In the first or second configuration, it is preferable that a surface of the light-shielding layer on the side of the light sensor element be provided with recesses and protrusions, that the surface of the light-shielding layer on the side of the light sensor element constitute a reflective part that reflects external light transmitted through the light sensor element such that the light is received by the light sensor element, and that the minimum thickness part of the light-shielding layer be a recess (third configuration).

With this configuration, it is possible to allow light that was transmitted through the light sensor element to enter the light sensor element again using the reflective part. The angle of reflection of the light changes due to the recesses and protrusions of the reflective part, and therefore, the length of the path through which the light passes through the light sensor element changes, allowing light with a long wavelength to be detected by the light sensor element.

In the above-mentioned configuration, by making the minimum thickness part of the light-shielding layer at least 100 nm in the case of a light sensor that uses visible light and at least 115 nm in the case of a light sensor that uses infrared light, as in the first and second configurations, light from the backlight or the like can be effectively prevented from being transmitted through the light-shielding layer.

In the third configuration, it is preferable that the light sensor element include a silicon layer, and that the silicon layer have recesses and protrusions that follow the recesses and protrusions of the light-shielding layer (fourth configuration).

With this configuration, it is possible to increase the surface area of the silicon layer compared to when the silicon layer of the light sensor element is flat. In other words, with the above configuration, it is possible to increase the light-receiving area of a photodiode, thus improving the performance of the photodiode.

Preferred embodiments of a semiconductor device of the present invention will be described with reference to drawings. The dimensions of the components in the drawings faithfully represent neither the dimensions of the actual components nor the dimensional ratios or the like of the components.

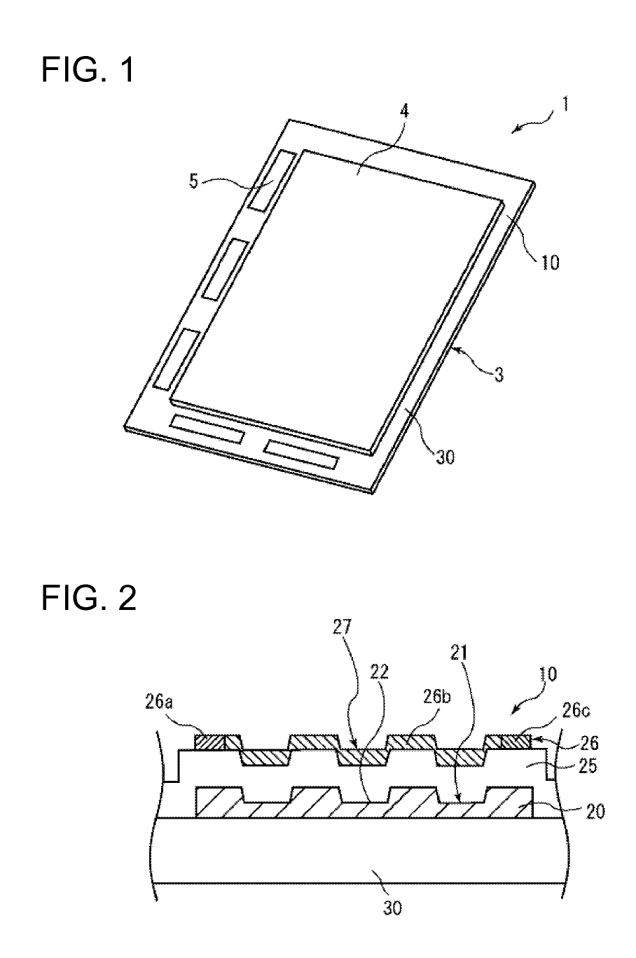

FIG. 1 shows a schematic configuration of a display panel of a liquid crystal display device 1 (display device) according to an embodiment. The display panel is provided with an active matrix substrate 3, an opposite substrate 4, and a liquid crystal layer (not shown in drawings) interposed therebetween. The display panel of the liquid crystal display device 1 of the present embodiment is equipped with a light sensor provided with a photodiode 10 (light sensor element) that reacts to external light and outputs a signal. Light from a backlight device, which is not shown in drawings, of the liquid crystal display device 1 illuminates the display panel.

The active matrix substrate 3 is provided with a substrate 30 upon which many pixels are formed in a matrix. The active matrix substrate 3 is also provided with a pixel electrode and a thin film transistor (hereinafter referred to as a TFT) for each pixel. The active matrix substrate 3 is additionally provided with photodiodes 10. The opposite substrate 4 is provided with an opposite electrode that faces the pixel electrodes and a color filter that has colored layers, although these are not shown in the drawings.

The liquid crystal display device 1 is configured so as to drive the TFTs of the active matrix substrate 3 according to signals from drivers 5 provided in the active matrix substrate 3, thus controlling the liquid crystals in the liquid crystal layer and displaying images in the display panel.

FIG. 2 shows a schematic configuration of the photodiode 10 provided in the active matrix substrate 3. In all of the drawings used in the descriptions below, only the conductors and semiconductors are shown with a hatching pattern.

The photodiode 10 is formed above a light-shielding film 20 (light-shielding layer) provided on the substrate 30. In other words, the light-shielding film 20 is provided between the photodiode 10 and the substrate 30. The substrate 30 is a transparent glass substrate that functions as a base substrate of the active matrix substrate 3. The light-shielding film 20 is made of a metal film (Mo, W/TaN, MoW, or Ti/Al, for example) with tantalum (Ta), titanium (Ti), tungsten (W), molybdenum (Mo), aluminum (Al), or the like as a main component. As a result of the light-shielding film 20, the illumination light from a backlight device, which is not shown in drawings, can be prevented from being inputted to the photodiode 10. In addition, the light-shielding film 20 also functions as a reflective film that reflects incident light. In other words, the surface of the light-shielding film 20 on the side of the photodiode 10 corresponds to the reflective part.

Recesses and protrusions 21 are formed on the surface of the light-shielding film 20, on the side opposite to the substrate 30, or in other words the surface on the side of the photodiode 10. Thus, a plurality of recesses 22 are provided on the surface of the light-shielding film 20 on the side of the photodiode 10, resulting in recesses and protrusions 21 being formed on the surface of the light-shielding film 20. As will be described below, the recesses 21 are formed such that the thickness of the light-shielding film 20 is at least 100 nm when the light incident from the substrate 30 side is visible light. If the light incident from the substrate 30 side is infrared light, then the recesses 21 are formed such that the thickness of the light-shielding film 20 is at least 115 nm.

A base coat 25 that serves as a base for the photodiode 10 is formed on the substrate 30 and the light-shielding film 20. The base coat 25 is an insulating film made of a silicon oxide film or the like, for example. The base coat 25 is formed through the CVD (chemical vapor deposition) method so as to cover the light-shielding film 20. As a result, the surface of the base coat 25 also has recesses and protrusions formed thereon, which follow the shapes of the recesses and protrusions 21 of the light-shielding film 20.

A silicon film 26 (silicon layer) is formed on the base coat 25. The silicon film 26 is also formed on the base coat 25 through the CVD method in a manner similar to the case of the base coat 25, and thus has recesses and protrusions 27 corresponding to the recesses and protrusions on the surface of the base coat 25. Also, the silicon film 26 has an n-type semiconductor region 26a, an intrinsic semiconductor region 26b, and a p-type semiconductor region 26c formed in this order along the surface direction. In other words, the n-type semiconductor region 26a and the p-type semiconductor region 26c are formed on the edges in the surface direction of the silicon film 26, and the intrinsic semiconductor region 26b is located in a region of the silicon film 26 where the recesses and protrusions 27 are formed. With this configuration, when light is incident upon the photodiode 10, a photocurrent is generated in the silicon film 26 of the photodiode 10, in a similar manner to conventional photodiodes.

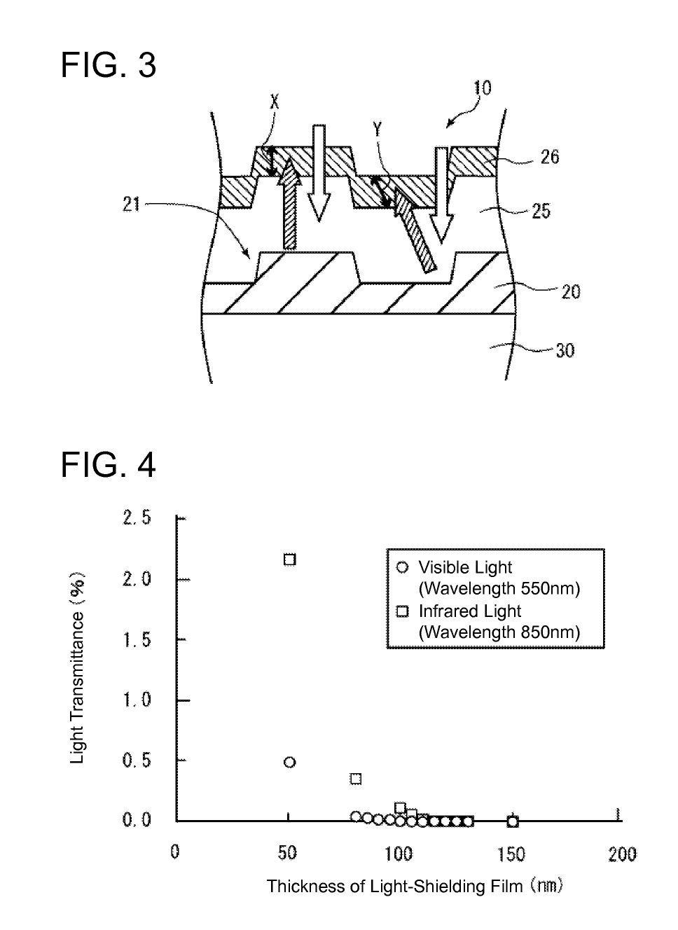

As shown in a magnified view in FIG. 3, with the above configuration, when light is incident (white arrows in the drawing) from the photodiode 10 side, the light reflects off (arrows with diagonal lines in the drawing) of a surface of the light-shielding film 20 (reflective part). Because the recesses and protrusions 21 are provided on the surface of the light-shielding film 20 on the side of the photodiode 10, the length Y of the path taken through the silicon film 26 by light reflected off of step parts of the recesses and protrusions becomes longer than the length X of the path taken through the silicon film 26 by the light reflected off of flat parts of the protrusions. With this configuration, the amount of long wavelength light that passes through the intrinsic semiconductor region 26b of the photodiode 10 increases. Therefore, the sensitivity of the photodiode 10 to long wavelength light can be increased.

The light radiated from the backlight device, which is not shown in drawings, to the substrate 30 side is shielded by the light-shielding film 20. As a result, the light radiated from the backlight device does not reach the photodiode 10, which reduces the susceptibility of the photodiode 10 to noise. Thus, the sensitivity of the photodiode 10 can be increased.

Also, by providing recesses and protrusions 21 on the surface of the light-shielding film 20 on the side of the photodiode 10 as described above, the surface area of the silicon film 26 of the photodiode 10 can be increased. In other words, because the silicon film 26 of the photodiode 10 also has recesses and protrusions, the surface area of the silicon film 26 can be made larger than if the silicon film of the photodiode were flat, if the region on the substrate 30 where the silicon film 26 is formed has the same area. As a result, the light-receiving area of the photodiode 10 can be increased, thus improving the performance of the photodiode 10.

The thickness of the light-shielding film 20, which has the above configuration, is at least 100 nm if the light incident from the substrate 30 side is visible light, and at least 115 nm if the light incident from the side of the substrate 30 is infrared light. In other words, the thinnest part of the light-shielding film 20 (the minimum thickness part where the recess 22 is formed) is formed to be at least 100 nm in thickness if the incident light is visible light and at least 115 nm in thickness if the incident light is infrared light. As a result, if the minimum thickness of the light-shielding film 20 is 115 nm, then both visible light and infrared light incident from the side of the substrate 30 can be shielded.

The above-mentioned film thicknesses were found by the present inventors through diligent effort to find a thickness of the light-shielding film 20 that does not allow light to be transmitted. FIGS. 4 and 5 show the relationship between the film thickness of the light-shielding film and the light transmittance. In FIGS. 4 and 5, the light-shielding film is formed of Mo and the light transmittance (%) was determined by radiating visible light with a wavelength of 550 nm and infrared light with a wavelength of 850 nm respectively onto the light-shielding film. FIG. 5 is a graph that shows a magnified view of a portion of the graph in FIG. 4 (in which the range of thickness of the light-shielding film is 90 nm to 150 nm).

As shown in FIGS. 4 and 5, the smaller the thickness of the light-shielding film is, the greater the light transmittance is. As shown in FIG. 5, in the case of visible light, when the thickness of the light-shielding film is at least 100 nm, the light transmittance is almost 0%. In the case of infrared light, when the thickness of the light-shielding film is at least 115 nm, the light transmittance is almost 0%. Therefore, in the case of visible light, if the thinnest part of the recesses and the protrusions 21 of the light-shielding film 20 (in other words, the recesses 22) has a thickness of at least 100 nm, then visible light is not transmitted through the light-shielding film 20. In the case of infrared light, if the minimum thickness of the light-shielding film 20 (the thickness of the recesses 22) is at least 115 nm, then infrared light is not transmitted through the light-shielding film 20.

### Manufacturing Method of Light-Shielding Film

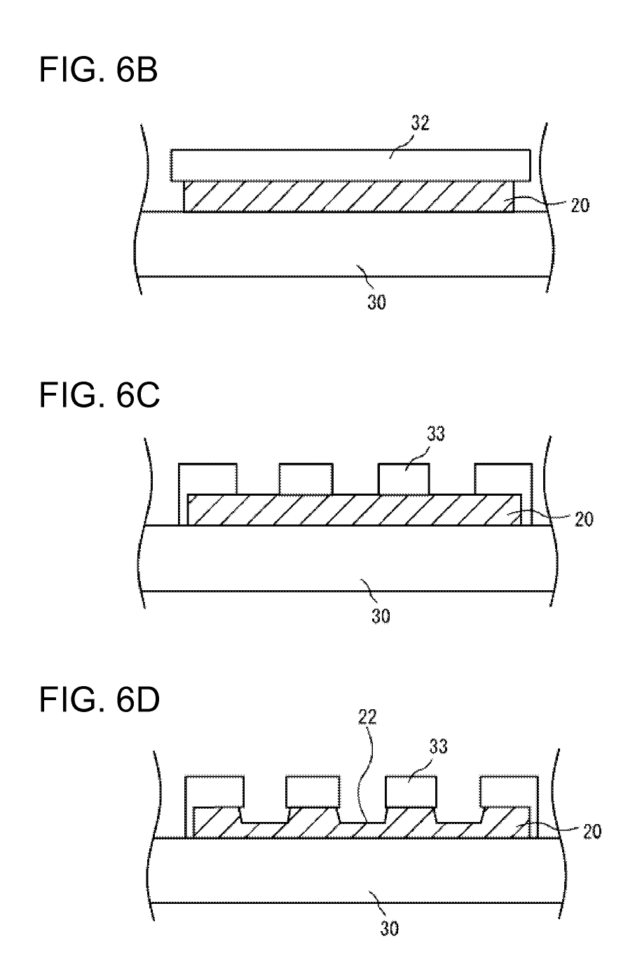

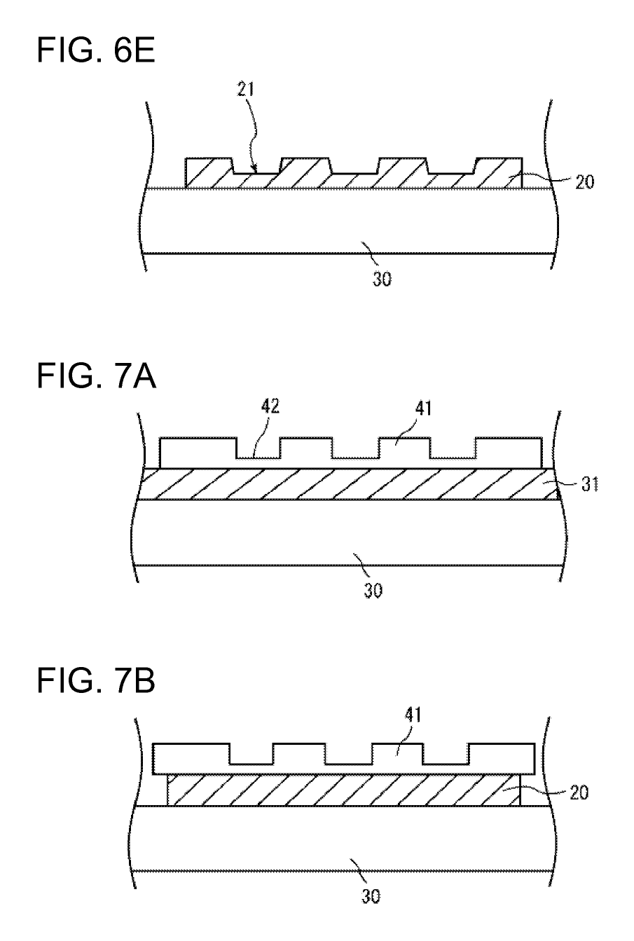

Next, the manufacturing method of the light-shielding film 20 having the above configuration will be described below. FIGS. 6A to 6E are drawings that show a simplified view of the manufacturing steps of the light-shielding film 20.

First, as shown in FIG. 6A, a light-shielding thin film 31 formed of a metallic material such as Mo is formed by the CVD (chemical vapor deposition) method, the sputtering method, or the like on the substrate 30. After that, a resist pattern 32 that covers the region where the light-shielding film 20 is to be formed is formed by photolithography on the light-shielding thin film 31.

Then, the light-shielding thin film 31 is etched using the resist pattern 32 as the mask, as shown in FIG. 6B. As a result, a light-shielding film 20 is formed. After that, the resist pattern 32 is removed.

Next, as shown in FIG. 6C, a resist pattern 33 with openings in regions where recesses 22 are to be formed on the light-shielding film 20 is formed on the light-shielding film 20 by photolithography. As shown in FIG. 6D, the light-shielding film 20 is etched using the resist pattern 33 as the mask, thus forming a plurality of recesses 22 on the light-shielding film 20. If visible light incident from the substrate 30 side is to be shielded by the light-shielding film 20, then the light-shielding film 20 is etched such that the thickness of the light-shielding film 20 at the recesses 22 is at least 100 nm. If infrared light incident from the substrate 30 side is to be shielded by the light-shielding film 20, then the light-shielding film 20 is etched such that the thickness of the light-shielding film 20 at the recesses 22 is at least 115 nm. Thereafter, by removing the resist pattern 33, a light-shielding film 20 having recesses and protrusions 21 on the surface thereof is formed, as shown in the FIG. 6E.

After the light-shielding film 20 is formed as described above, a base coat 25 and a silicon film 26 are formed by the CVD method on the light-shielding film 20, although this is not shown in the drawings. A portion of the silicon film 26 is doped through ion implantation or the like, thus forming the n-type semiconductor region 26a and the p-type semiconductor region 26c. As a result, a photodiode 10 as shown in FIG. 2 is formed.

### Effects of the Embodiment

In the present embodiment, recesses and protrusions 21 are formed on the surface of the light-shielding film 20 on the side of the photodiode 10, thus allowing the photodiode 10 to detect long wavelength light with a high sensitivity. As a result, the detection accuracy of the photodiode 10 for long wavelength light can be improved. In the present embodiment, the thinnest part of the light-shielding film 20 (in other words, the recesses 22 in the recesses and protrusions 21) has a thickness of at least 100 nm when the light incident from the substrate 30 side is visible light, and at least 115 nm when the light is infrared light, in the above configuration. As a result, it is possible to prevent visible light or infrared light from being transmitted through the light-shielding film 20. Therefore, it is possible to prevent light from the backlight device or the like from entering the photodiode 10, and thus the detection accuracy of the photodiode 10 can be improved.

### Modified Embodiment

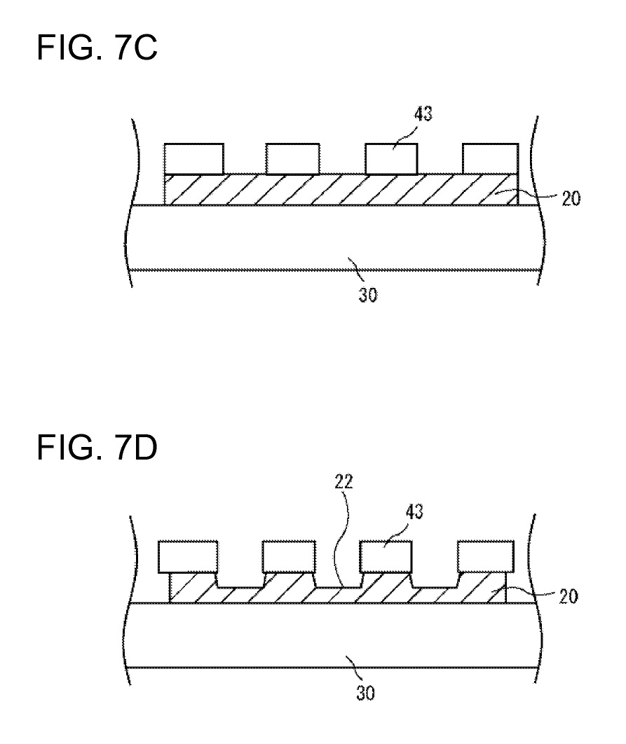

In this modified embodiment, the method of forming the light-shielding film 20 is different from that of the above embodiment, as shown in FIGS. 7A to 7D. In the above embodiment, in order to form the light-shielding film 20, two resist patterns 32 and 33 are formed, as shown in FIGS. 6A to 6E. However, in the modified embodiment, the light-shielding film 20 is formed by forming one resist pattern. In the description below, configurations that are the same as those of the embodiment above are given the same reference characters and descriptions thereof are omitted.

First, as shown in FIG. 7A, a light-shielding thin film 31 is formed on the substrate 30. Then, a resist pattern 41 is formed by photolithography on the light-shielding thin film 31 so as to be thinner in regions where the recess 22 is to be formed on the light-shielding film 20 than in other parts. In other words, the resist pattern 41 has a plurality of recesses 42, which are thinner.

As shown in FIG. 7B, the light-shielding thin film 31 is etched using the resist pattern 41 as a mask. As a result, the light-shielding film 20 is formed.

Next, as shown in FIG. 7C, mainly the thin parts of the resist pattern 41 are removed through plasma ashing in which oxygen gas is made into a plasma, thus breaking down the photoresist. As a result, an island-shaped resist pattern 43 is formed. Then, the light-shielding film 20 is etched using the resist pattern 43 as a mask, as shown in FIG. 7D. As a result, recesses 22 are formed in parts where the resist pattern 43 is not present. By removing the resist pattern 43, a light-shielding film 20 with the shape shown in FIG. 6E can be attained.

### Other Embodiments

Embodiments of the present invention have been described above, but the above embodiments are merely examples of implementations of the present invention. The present invention is not limited to the above embodiments, and can be implemented by appropriately modifying the above embodiments without departing from the spirit thereof.

In the aforementioned embodiments, recesses and protrusions 21 are provided on the surface of the light-shielding film 20 on the side of the photodiode 10. However, recesses and protrusions do not need to be provided on the surface of the light-shielding film. Even in such a case, the minimum thickness of the light-shielding films needs to be at least 100 nm if the incident light is visible light and at least 115 nm if the incident light is infrared light.

### INDUSTRIAL APPLICABILITY

The display device according to the present invention is applicable as a display device provided with a semiconductor device having a light-shielding film.

1. A display device, comprising:
a light sensor element formed on a substrate that constitutes a part of a display panel; and
a light-shielding layer formed between the substrate and the light sensor element,
wherein a thickness of a minimum thickness part of the light-shielding layer is at least 100 nm.

2. The display device according to claim 1, wherein the thickness of the minimum thickness part of the light-shielding layer is at least 115 nm.

3. The display device according to claim 1, wherein a surface of the light-shielding layer on the side of the light sensor element is provided with recesses and protrusions,
wherein the surface of the light-shielding layer on the side of the light sensor element constitutes a reflective part that reflects external light transmitted through the light sensor element such that the light is received by the light sensor element, and
wherein the minimum thickness part of the light-shielding layer is a recess.

4. The display device according to claim 3, wherein the light sensor element comprises a silicon layer, and
wherein the silicon layer has recesses and protrusions that follow the recesses and protrusions of the light-shielding layer.
